(19) United States
(12) Patent Application Publication
(10) Pub. No.: US 2023/0278448 A1
(43) Pub. Date: Sep. 7, 2023

(54) ELECTRIC METER COLLAR HOUSING ELECTRIC VEHICLE SUPPLY EQUIPMENT

(71) Applicant: Eclipse DC LLC, Winnabow, NC (US)

(72) Inventor: Anthony Riccardi, III, Winnabow, NC (US)

(21) Appl. No.: 18/177,090

(22) Filed: Mar. 1, 2023

Related U.S. Application Data
(60) Provisional application No. 63/315,333, filed on Mar. 1, 2022.

(51) Int. Cl. B60L 53/62; G01R 22/06; H02H 3/16; B60L 53/18

(52) U.S. Cl. CPC B60L 53/62; G01R 22/065; G01R 22/063; H02H 3/16; B60L 53/18

(57) ABSTRACT

An electric meter collar housing an electric vehicle supply equipment (EVSE) therewith. The collar is configured to be located between the electric meter receptacle and the electric meter. The collar includes a fused disconnect, a controller, an EV connector inlet, a relay, a ground fault circuit interrupter (GFCI) current transformer, and first and second current transformers. The fused disconnect provides an external switch and external fuses. The EV connector inlet has a plurality of insulated receptacles to receive pins of an untethered EV cable. The relay is coupled between the fused disconnect and the EV connector inlet and is controlled by the controller. The GFCI current transformer is coupled between the relay and the EV connector inlet to detect ground faults during EV charging. The first and the second current transformers are to measure current utilized during EV charging.

### BACKGROUND

Electric vehicles (EVs) continue to grow in popularity. Accordingly, the need for EV supply equipment (EVSE) to provide charging for the EVs continues to increase. Commercial EVSEs are now located in many store parking lots and other locations. While EVs may be charged by plugging them into a standard 120V outlet, this charging may take a rather long time. Home EVSEs that provide rapid charging are now available. However, the home EVSEs require that a 240V outlet be available in an appropriate location to plug the home EVSE into the 240V outlet. Additionally, the 240V outlet requires its own breaker to be available in a breaker box for the home. An electrician is likely required to install the breaker and 240V outlet. The need to utilize an electrician increases the cost of installing the home EVSE. Furthermore, plugging an EVSE into a 240V outlet results in the charges associated with the EVSE being added to the standard electric bill.

What is desirable is an easier manner for providing home EVSEs that does not require a 240V outlet or a dedicated breaker and may not require an electrician for installation. Furthermore, it would be desirable to have an EVSE that provides insight into the amount of electricity utilized thereby and could possibly be monitored and billed separately.

### BRIEF DESCRIPTION OF THE DRAWINGS

The structure, objects, and advantages of an electric vehicle supply equipment (EVSE) not requiring an individual 240V outlet and corresponding breaker and also providing ability to track consumption of the EVSE separately will be understood by referring to the detailed description of illustrative embodiments in conjunction with the accompanying technical drawings, in which:

FIGS. 1A-B illustrate an exploded and a prospective view of an example electrical interface.

FIG. 1C illustrates a simple schematic diagram of the example electrical interface.

FIG. 2 illustrates a high-level block diagram of an example electrical interface having an EVSE incorporated therein, according to one embodiment.

FIGS. 3A-B illustrate an exploded and a prospective view of an example electrical interface having an EVSE incorporated therein, according to one embodiment.

FIG. 3C illustrates a simple schematic diagram of the example electrical interface having an EVSE incorporated therein, according to one embodiment.

FIG. 4 illustrates a detailed schematic diagram of an example electrical interface having an EVSE incorporated therein, according to one embodiment.

FIGS. 5A-C illustrate various views of an example meter collar to show how it would connect between the meter receptacle and the meter, according to one embodiment.

FIGS. 6A-B illustrate various views of an example meter collar configured for installation, according to one embodiment.

FIGS. 7A-C illustrate various views of an example meter collar showing components internal thereto, according to one embodiment.

FIG. 8 illustrates an example connection between the EV inlet connector and an EV cable, according to one embodiment.

FIG. 9A-B illustrate a perspective and exploded view of the example collar connected to an electrical interface via the meter receptacle in the housing, according to one embodiment.

FIG. 10 illustrates an example process flow of the EV controller monitoring and controlling EV charging, according to one embodiment.

FIGS. 11A-C illustrate an example untethered EV cable that could be utilized to provide connectivity and charging between EVSEs and EVs, according to one embodiment.

### DETAILED DESCRIPTION

An electrical interface is a point where electricity is provided to a building (e.g., house, office building, apartment complex) from a utility company. The electrical interface may be located external to the building (e.g., on an exterior wall). The electrical interface provides the electricity to a breaker box within the building and the electricity is then distributed within the building. The electrical interface is equipped with a meter to monitor electric usage within the building (consumer usage) so the utility company can bill the consumer for their usage.

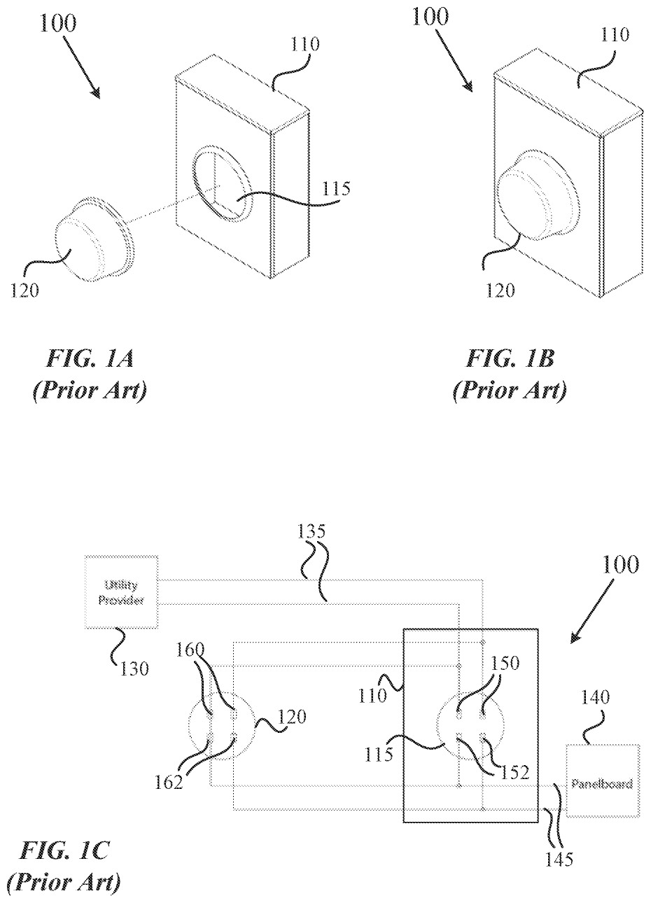

FIGS. 1A-B illustrate an exploded and a prospective view of an example electrical interface 100. The electrical interface 100 receives the electricity from a utility provider (not illustrated) and provides it to a customer (not illustrated). The electrical interface 100 includes a housing 110 having a receptacle 115 for receiving an electric meter (e.g., watt hour meter) 120 that is utilized to monitor consumption by the customer.

FIG. 1C illustrates a simple schematic diagram of the example electrical interface 100. Electricity (e.g., 240V) is received from a utility provider (electric company) 130 via two supply lines 135 and is provided to a consumer (e.g., panel board) 140 via two load lines 145. The receptacle 115 includes two supply sockets 150 and two load sockets 152 that are utilized to connect to a corresponding two supply connectors 160 and two load connectors 162 in the meter 120. It should be noted that the sockets 150, 152 and the connectors 160, 162 are simply illustrated as boxes for ease of illustration. This arrangement connects both the supply lines 135 and the load lines 145 to the meter 120 so the meter can monitor usage by the consumer 140. The electric meter 120 may be grounded (grounding not illustrated). It should be noted that some electric meters 120 are grounded while others are not.

An electrical interface may be modified to provide an electric vehicle supply equipment (EVSE) therewithin. Having an EVSE located with an electrical interface (e.g., external to the building) may be desirable depending on the location of the electrical interface. Furthermore, locating the EVSE with the electrical interface eliminates the need for a 240V outlet to plug the EVSE into and the need for a specific breaker in the breaker box for the 240V outlet as the EVSE can receive the 240V at the electrical interface.

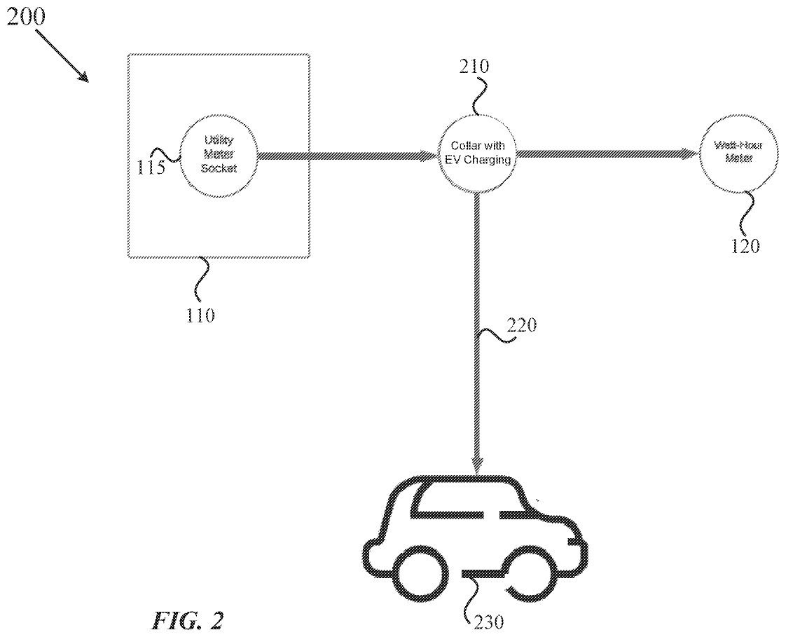

FIG. 2 illustrates a high-level block diagram of an example electrical interface 200 having an EVSE incorporated therein. The EVSE is located within a collar 210 located between the meter receptacle 115 and the meter 120. The collar 210 may include connectors for plugging into corresponding sockets in the meter receptacle 115 and sockets to receive corresponding connectors of the meter 120. The collar 210 may include all the electronics necessary to create the EVSE. The collar 210 includes an EV charging cable 220 connected thereto. According to one embodiment, the EV charging cable 220 may be tethered to the collar 210. Alternatively, the cable 220 may be untethered and include a connector for being received by an inlet in the collar 210. The other end of the EV charging cable 220 is plugged into an EV 230 in order to charge the EV 230.

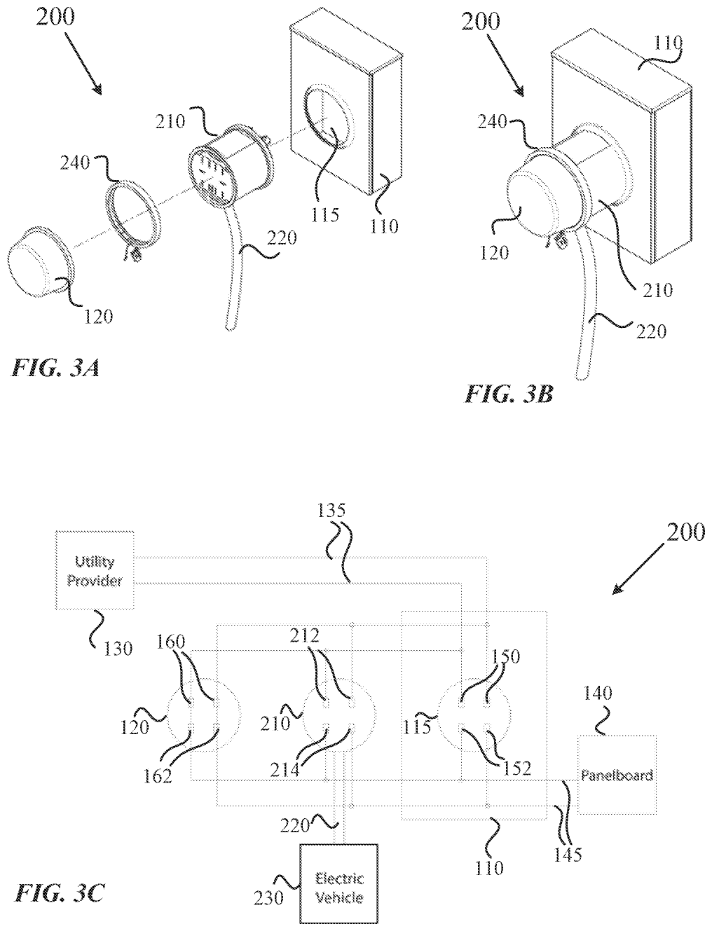

FIGS. 3A-B illustrate an exploded and a prospective view of an example electrical interface 200 having an EVSE incorporated therein. The receptacle 115 receives the collar 210 and the collar 210 receives the electric meter 120. The meter 120 is secured to the collar 210 with a lockable bracket 240. An EV charging cable 220 is connected to the collar 210. The charging cable 220 may be tethered to the collar 210 or may include a connector (not illustrated) that is plugged into an inlet (not illustrated) in the collar 210. The other end of the cable 220 is to be plugged into an EV.

FIG. 3C illustrates a simple schematic diagram of the example electrical interface 200 having an EVSE incorporated therein. The collar 210 is located between the receptacle 115 and the meter 120. The collar 210 includes two supply lines 212 and two load lines 214 running therethrough. Each of the lines 212, 214 may be provided by a jaw blade that is a metal (e.g., copper) bar that has a second metal bar mounted on one end where the gap between the bars provides a socket for receiving another bar (connector). The end of the jaw blade that is simply the bar (connector) faces the receptacle 115 and the end with the socket faces the meter 120. For ease of illustration the lines 212, 214 (jaw blades) are simply illustrated as boxes. The connectors of the collar 210 are plugged into the sockets 150, 152 in the receptacle 115 and the connectors 160, 162 in the meter 120 are plugged into the sockets in the collar 210. This arrangement connects the supply lines 135 to the load lines 145 via the collar 210 and the meter 120. The EV charging cable 220 (tethered or untethered) is connected to the collar 120.

As illustrated, the charging cable 220 (and associated EV charging functionality which is not illustrated) is connected to the load (consumer) side so that the consumption of electricity thereby is captured the same as any other consumption by the consumer (by the watt hour meter 120). Alternatively, the charging cable 220 (and associated EV charging functionality) may be provided on the supply side (incoming power lines). Connecting the EV charging functionality to the supply side provides the ability to independently track the electrical consumption associated with EV charging.

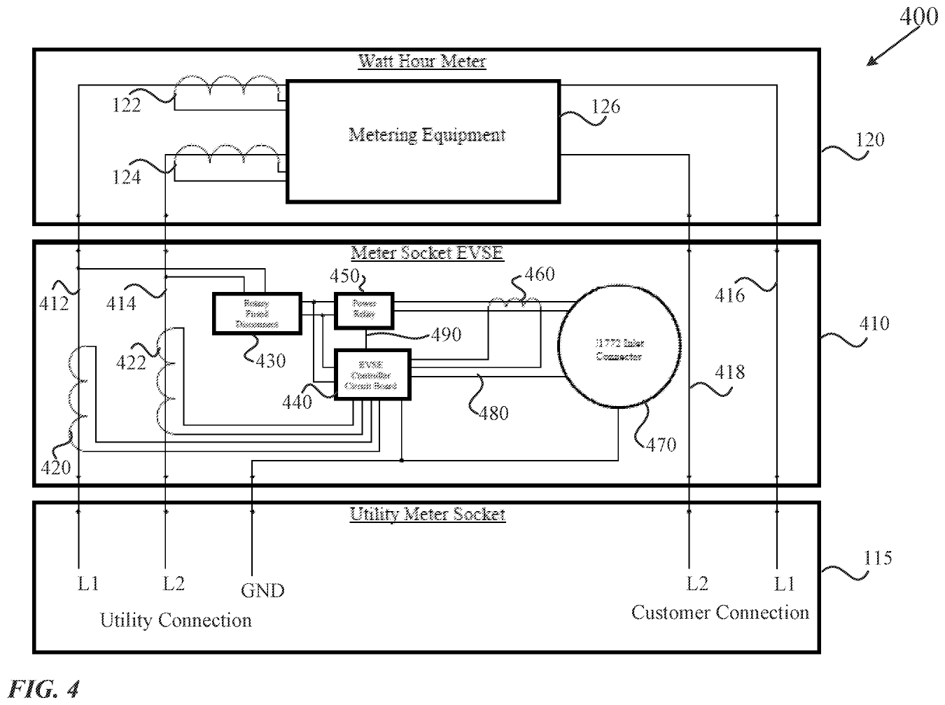

FIG. 4 illustrates a detailed schematic diagram of an example electrical interface 400 having an EVSE incorporated therein. The electrical interface 400 includes the utility meter socket (receptacle) 115, a collar 410 and the meter (watt hour meter) 120. The receptacle 115 receives power (240V) from the utility company via two supply lines (L1, L2) each providing alternating 120V and being 180 degrees out of phase from one another. The receptacle 115 provides the power (240V) to the customer via two corresponding load lines (L1, L2) each providing alternating 120V and being 180 degrees out of phase from one another. The collar 410 includes a pair of supply lines 412, 414 (e.g., jaw blades 212) and a pair of load lines 416, 418 (e.g., jaw blades 214). The meter 120 is connected to the collar 410. The power flows from the utility company to the supply lines of the receptacle 115, from the receptacle 115 to the supply lines 412, 414 of the collar 410, from the collar 410 to the supply lines of the meter 120, through the meter 120, from the load lines of the meter 120 to the load lines 416, 418 of the collar 410, from the collar 410 to the load lines of the receptacle 115, and from the receptacle 115 to the customer.

The collar 410 may include a pair of current transformers 420, 422, a fused disconnect 430, an EV controller (circuit board) 440, a power relay 450, a ground fault circuit interrupter (GFCI) current transformer 460 and an EV inlet connector (e.g., J1772 connector) 470. The power from both supply lines 412, 414 is utilized to provide 240V for fast charging of the EVs. The power from the supply lines 412, 414 is provided to the EV controller 440 via the fused disconnect 430 and to appropriate pins of the EV inlet connector 470 via the fused disconnect 430 and the power relay 450. The EV controller 440 and the EV inlet connector 470 are grounded.

The fused disconnect 430 is designed to provide an external emergency switch for turning off power to the collar 410 as well as an external fuse for each of the supply lines 412, 414. It should be noted that United Laboratories (UL) requires an external manual switch to cut power in emergencies and also requires external devices (e.g., breaker, fuse) capable of cutting power in the event of an over current. The fused disconnect 430 is located external to the collar 410 and is plugged into an inlet in the collar 410. The inlet is connected to the supply lines 412, 414 so that it is powered. When the fused disconnect 430 is plugged into the inlet it becomes powered. When the fused disconnect 430 is turned to an ON position it activates a microswitch. The activation of the microswitch notifies the EV controller 440 that the switch is in an ON position so the EV controller 440 may become operational. When the fused disconnect 430 is turned to the OFF position it deactivates the microswitch. The deactivation of the microswitch means that the EV controller 440 is not notified that the switch is in an ON position so the EV controller 440 will not become operational.

The fused disconnect 430 includes a fuse therewithin associated with each of the supply lines 412, 414. When the current on a supply line 412, 414 exceeds a defined current the fuses open so the power from the supply lines is not provided to the EV controller 440 and the power relay 450. The size of the fuse utilized may vary depending on various factors including the current rating of the supply lines (jaw blades). Standard fuse sizes may be in the range of 30A-50A but are in no way intended to be limited thereby. For example, if available a 100A could be utilized without departing from the current scope. As one skilled in the art would recognize, the higher the amperage that is utilized the quicker the EV may be charged.

The current transformers 420, 422 are to measure the current (calculate the wattage) utilized for EV charging by each of the supply lines 412, 414. The current used on each line 412, 414 is provided to the EV controller 440. The EV controller 440 utilizes this information for metering the electricity used for EV charging.

An EVSE (e.g., collar 410) and an EV communicate with each other regarding the charging status via a pilot wire in an EV cable. The pilot wire is to provide information regarding, for example, whether an EV is plugged into the EV charging cable, whether charging is occurring, charging is complete, or an emergency stop is initiated. Different EVs may control the charging process in different manners. The emergency stop may be initiated by the EV and/or may be initiated by activating a button on the EV charging cable. The EV controller 440 is connected to a receptacle of the EV inlet connector 470 associated with the pilot wire (connectors of the inlet are not illustrated) via a pilot wire connection 480. Initially, the EV controller provides a constant 12V to the pilot wire while it is waiting for connectivity. When an EV is connected to the EV cable the voltage on the pilot wire drops to 9V based on a resistor within the EV. When the EV controller 440 detects this drop in voltage it initiates a charging sequence that if accepted by the EV results in another voltage drop and initiation of charging.

The GFCI current transformer 460 is utilized to determine if there are any ground fault conditions between the power relay 450 and the EV and provides that information to EV controller 440. The power relay 450 is utilized to ensure that power is provided to the EV inlet connector 470 only when appropriate. For example, power should only be provided to the EV inlet connector 470 when an EV charging cable is secured thereto, an EV is plugged into other end of the EV charging cable and the EV is ready and able to receive a charge (as discussed briefly above with respect to pilot wire). This prevents power from being provided inadvertently to, for example, a human touching the EV inlet connector 470 or the EV charging cable and/or overcharging an EV. The power relay 450 is controlled by the EV controller 440. The EV controller 440 provides a desired voltage (e.g., 12V) across the terminals of the relay 450 via connection 490 (illustrated as single line for ease of illustration but should be a line to each terminal) to activate (close) the relay 450 so that power is provided to the EV inlet connector 470. When the voltage is not provided the relay 450 is deactivated (opened) so that power is not provided to the EV inlet connector 470. According to one embodiment, the power relay 450 is a mechanical relay. Alternatively, the power relay 450 could be a solid-state relay.

The EV controller 440 may monitor and control EV charging as well as provide communications with a service provider and possibly other entities. The communications may include providing information regarding usage necessary for billing thereof and for internet of things (IoT) including maintenance. According to one embodiment, the EV charging functionality and the communications functionality are provided by components on a single board (or possibly a single integrated circuit). Alternatively, the EV charging functionality may be provided by components on one board (or IC) while the communications functionality may be provided by components on a separate board (or IC). If separate boards (or ICs) were required additional current transformer(s) may be required as each board (or IC) would need to know the current being utilized on each line (e.g., the EV charging board needs the current measurements to ensure proper operation of the EVSE and the communications board needs the current measurements for revenue tracking (billing)).

The EV controller 440 may include a DC power supply that steps down the 240V AC (+120V, −120V) received via the supply lines 412, 414 to appropriate DC voltages needed for operations. For example, the power supply may convert the 240V AC to +12V DC and −12V DC for operation of the pilot wire and possibly the relay 450. The power supply may also convert the 240V AC to +5V DC or +3.3V DC to control the components on the board (voltage being dependent on components utilized). As noted above, if separate boards are utilized for EV charging and communications, each board may require a power supply.

The meter 120 includes current transformers 122, 124 on each load line to calculate the current utilized by the customer. The current used on each line is provided to the watt hour meter 126 that tracks the power usage provided by the electrical interface 400. As the current utilized by the EVSE is tracked on the supply side it is not captured by the watt hour meter 126. Rather, the EVSE usage is captured separately.

As illustrated, the various components within the collar 410 utilized for EV charging (the EVSE) are connected to the supply side. It should be noted that if the EVSE was connected to the load side instead of the supply side that the watt hour meter 126 would track power usage of the EVSE as well as all other usage. Accordingly, billing for EV usage separately would be more complicated. The EV controller 440 may still monitor the electric usage of the EVSE separately, but the usage would already be included in the usage captured by the watt hour meter 126. Therefore, to bill separately the service provider would have to subtract the usage of the EVSE from the watt hour meter usage to get non-EV charging consumer usage. The service provider could then bill the EV usage and the non-EV usage separately. Alternatively, the service provider could monitor EVSE usage and then either bill a surcharge or provide a discount for the EVSE usage portion of the bill.

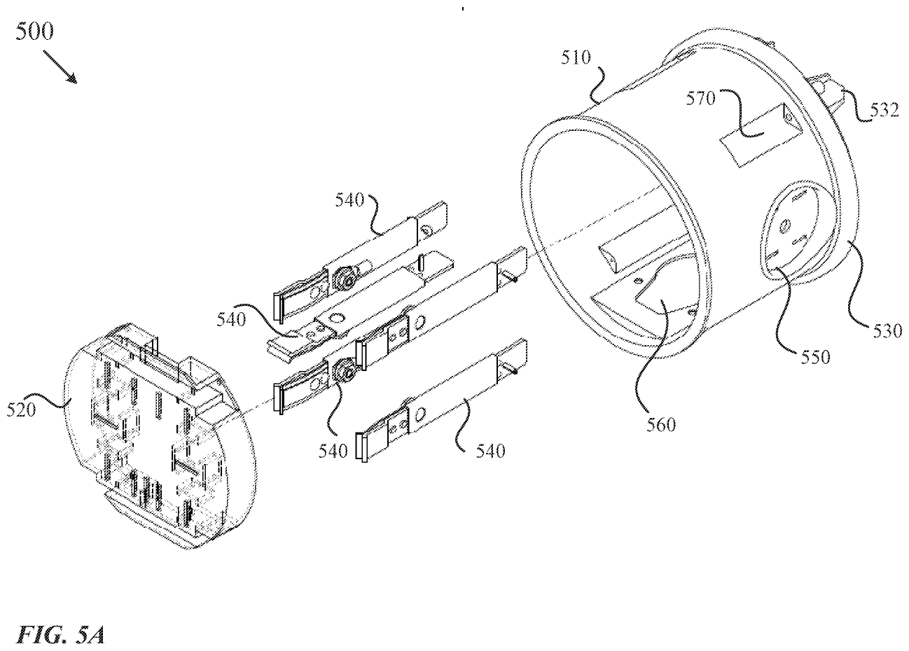

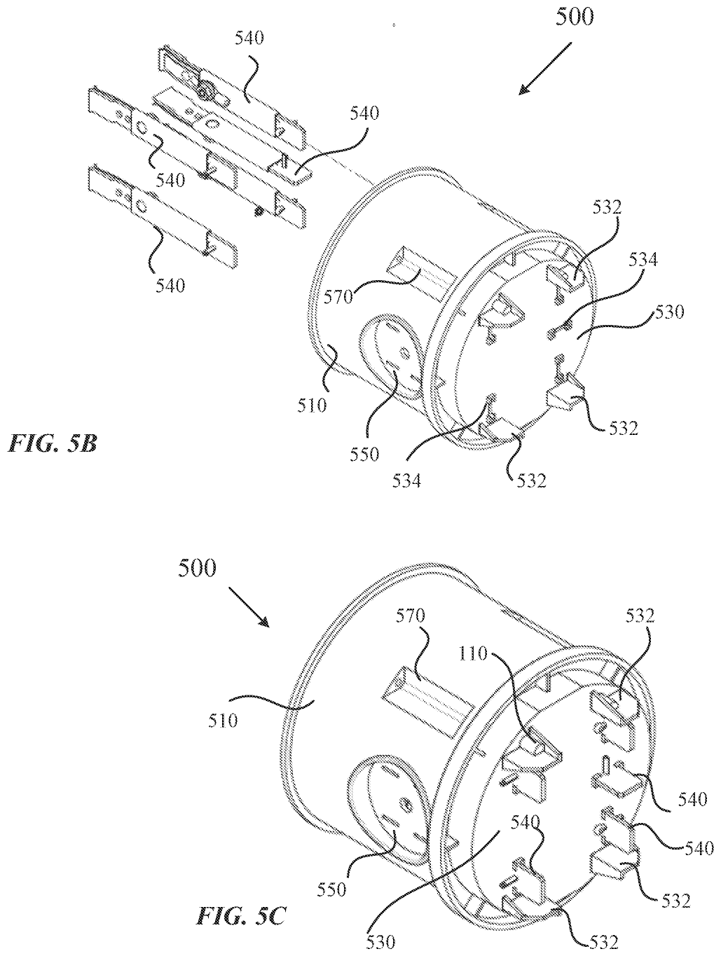

FIGS. 5A-C illustrate various views of an example meter collar 500 to show how it would connect between the meter receptacle 115 and the meter 120. The meter collar 500 includes a housing 510, a front cover 520, a back cover 530 and a plurality of jaw blades 540. It should be noted that four jaw blades 540 are illustrated (three for power and one for ground) for ease of illustration. A meter collar will typically include four power jaw blades (two for load lines, two for supply lines) or a total of five jaw blades (four for power and one for grounding). If the meter collar 500 includes a ground jaw blade, the ground jaw blade is utilized to ground the EV controller 440 and the EV inlet connector 470. If the meter collar 500 does not includes a ground jaw blade, a ground wire is connected to the EV controller 470 and the EV inlet connector 470 and extends from the collar for being secured to a ground terminal in the electric meter receptacle to provide grounding thereto.

The socket end of the jaw blades 540 face the front cover 520. The front cover 520 includes a plurality of slits (not identified) that are aligned with the socket of the jaw blades 540 to allow electrical connectors from a meter 120 to pass therethrough for electrically connecting the meter 120 and the collar 500. The front cover 520 also includes a plurality of slits (not identified) to receive tabs from a meter 120 to assist in aligning the meter 120 with the collar 500 and securing the meter 120 therein.

The back cover 530 includes a plurality of tabs 532 and a plurality of slits 534. The tabs 532 are to align and help secure the collar 500 in a meter receptacle 115. The slits 534 are to enable the jaw blades 540 to pass therethrough so that they can be received by sockets of the meter receptacle 115 for electrically connecting the meter receptacle 115 and the collar 500. The housing 510 includes a powered receptacle 550 for receiving a fused disconnect 430, an opening 560 for providing access to the EV inlet connector 470 and a latch 570 for securing covers (not shown) in a closed configuration.

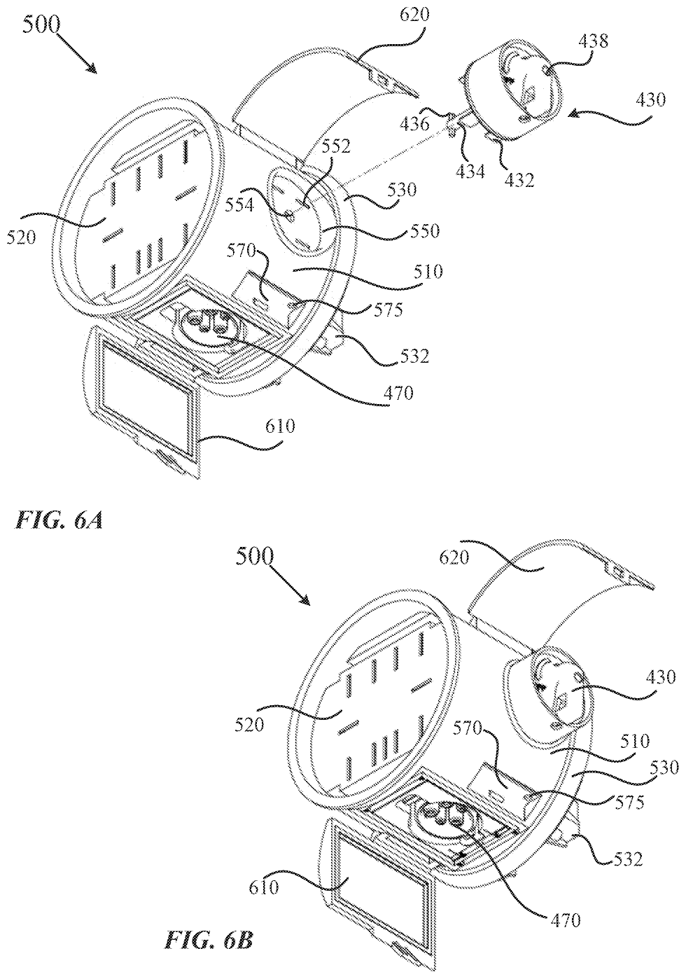

FIGS. 6A-B illustrate various views of an example meter collar 500 configured for installation. The meter color 500 includes the EV inlet connector 470 mounted therein. Access to the EV inlet connector 470 is provided by the opening 560. A first hinged cover 610 is secured to the housing 510 for covering the EV inlet connector 470 when an EV cable is not connected thereto. The first hinged cover 610 may be secured to the latch 570 when closed. A second hinged cover 620 is secured to the housing 510 for covering the receptacle 550 when the fused disconnect 430 is not connected thereto. The first hinged cover 610 may be secured to the latch 570 when closed. The latch 570 may include an LED 575 that provides the status of EV charging when in operation.

The receptacle 550 includes four sockets 552 (only one identified for ease of illustration) to receive an associated four tabs 432 (only one identified for ease of illustration) in the fused disconnect 430. Two of the sockets of the receptacle 550 are powered by the lines L1 and L2 (either supply or load side depending on configuration). The receptacle 550 provides the power to the fused disconnect 430 via the connection of the powered sockets 552 and the associated tabs 432. The power is provided to the fuses within the fused disconnect 430 to ensure current being drawn is not above a threshold. As long as the fuses are not tripped the power is provided to the other sockets 532 of the receptacle 550 via the associated tabs 432 of the fused disconnect 430. The receptacle 550 also includes a hole 554 for enabling a pin 434 of the fused disconnect 430 to pass therethrough. The end of the pin 434 includes a tab 436 that activates a microswitch (not illustrated) on a back end of the receptacle 550 when the fused disconnect 530 is turned to an ON position. The fused disconnect includes a handle 438 for easy rotation of the fused disconnect between an ON and OFF position.

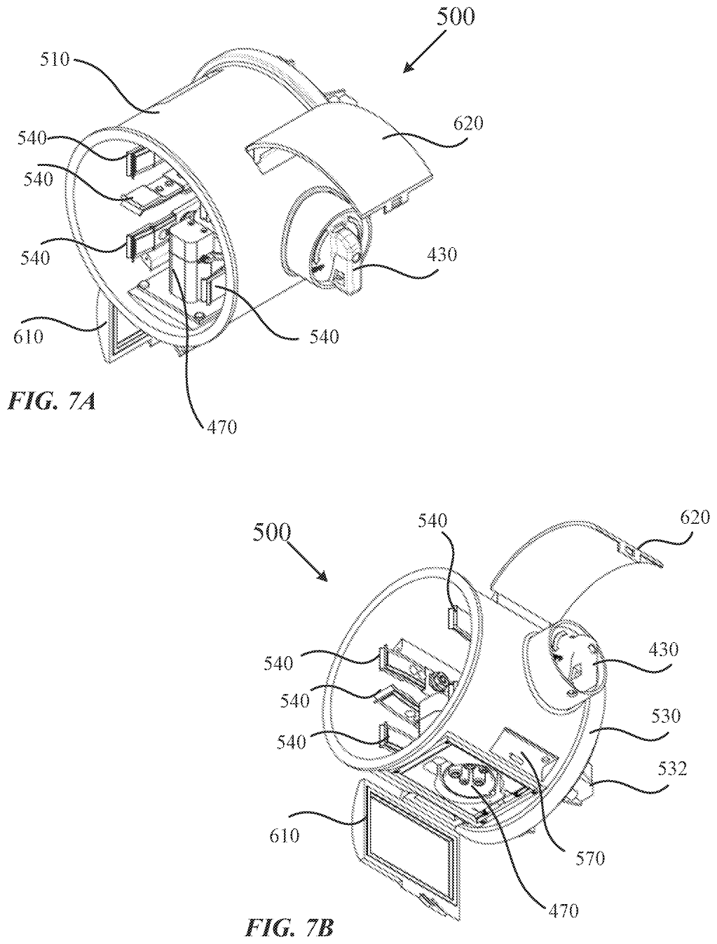

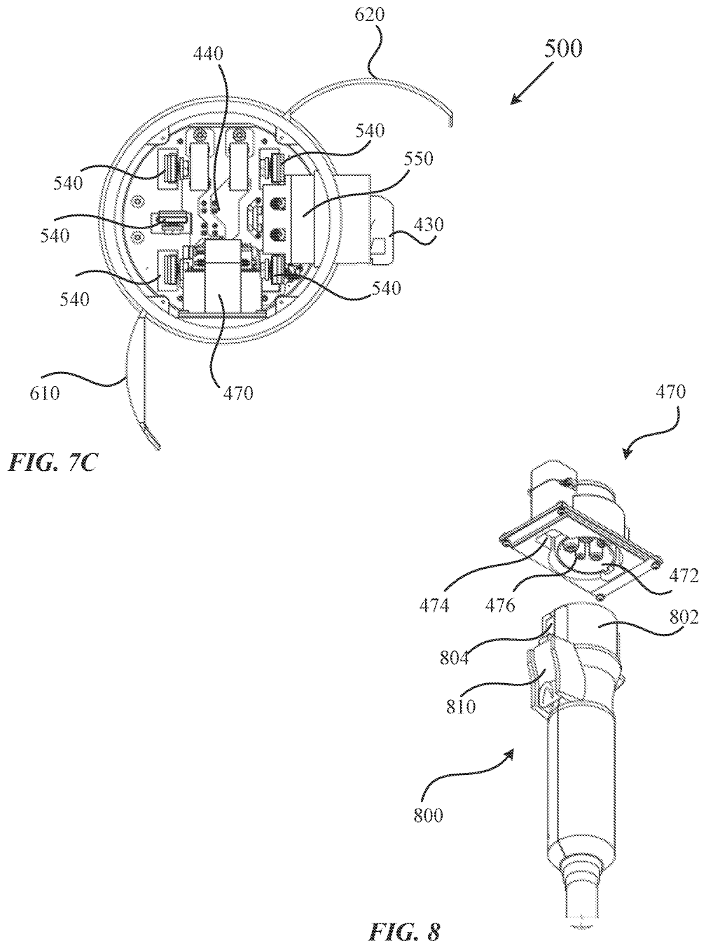

FIGS. 7A-C illustrate various views of an example meter collar 500 showing components internal thereto. The inlet EV inlet connector 470 is mounted internal to the housing 510 and is accessible via the opening 560 in the housing 510. The jaw blades 540 extend from front to back of the housing 510. The EV controller 440 (illustrated as various components on a board) is located within the housing 510. As illustrated, the EV controller 440 is located between the jaw blades 540 but is not limited thereto. The receptacle 550 receives the fused disconnect 430. The relay 450, the current transformers 420, 422 and the GFCI current transformer 460 are not illustrated for ease of illustration.

FIG. 8 illustrates an example connection between the EV inlet connector 470 and an EV cable 800. The connector 470 includes an opening 472 having a plurality of insulated receptacles 476 extending therefrom. The cable 800 includes a head 802 that is received with the opening 472. While not visible the head 802 includes a plurality of holes with pins located therein in alignment with the plurality of insulated receptacles 476. The pins are received in the insulated receptacles 476. The connector 470 includes a notch 474 to receive a latch 804 of the cable 800. The latch 804 and the notch 474 secure the cable 800 within the connector 470. The cable 800 includes a button 810 connected to the latch 804 that causes the latch 804 to disengage from the notch 474 when depressed. The connector 470 may provide the EV controller 430 an indication that the cable 800 is connected (e.g., is latched).

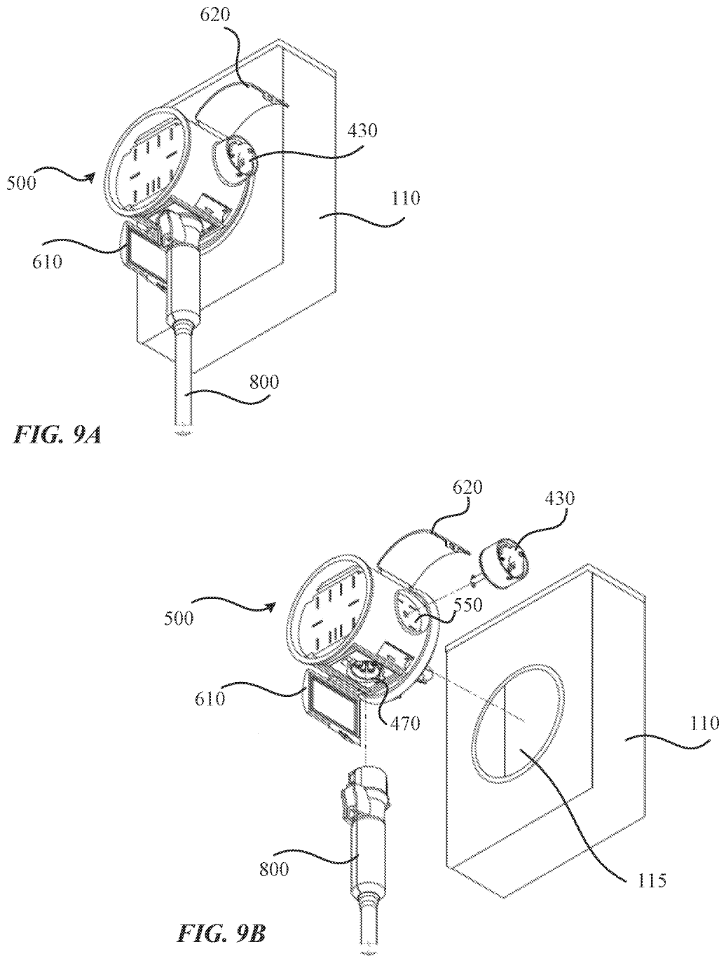

FIG. 9A-B illustrate a perspective and exploded view of the example collar 500 connected to an electrical interface via the meter receptacle 115 in the housing 110.

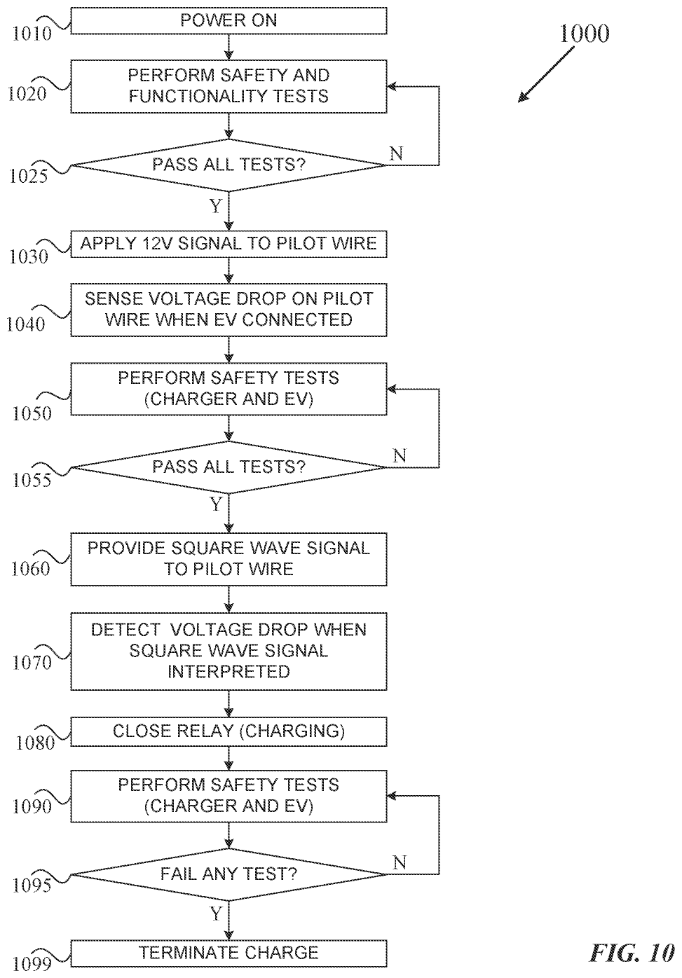

FIG. 10 illustrates an example process flow 1000 of the EV controller monitoring and controlling EV charging. Initially power is provided to the EV controller 1010. Once powered, the controller (circuit board) runs through a series of safety/functionality checks (e.g., Continuous Ground Monitoring test, Relay Functionality test, Ground Fault test, J1772 Latch Status test, Fuse Position test, Ampacity test and Thermal test) 1020. Once all checks have passed (1025 Yes), the pilot wire initiates a constant +12 VDC signal while waiting to plug into an EV (State A) 1030. Once an EV is connected, the circuit board senses the drop from +12 VDC to +9 VDC due to a resistor within the EV (State B) 1040. At this point, both the EV and the controller run through their checks again to confirm they can initiate the charge 1050. Once all checks have passed (1055 Yes), the controller converts the 9 VDC static signal to a +9 VDC/−12 VDC square wave signal at 1 KHz 1060. The duty cycle of the square wave (Time high/Time low) is how the allowable ampacity is communicated from the controller to the EV. The Society of Automotive Engineers (SAE) set these standards for manufacturers to follow.

Once the EV sees the 1 KHz square wave and interprets the duty cycle, it then introduces a second resistor to drop the voltage from +9 VDC/−12 VDC to +6 VDC/−12 VDC (or +3 VDC/−12 VDC if the battery chemistry within the EV requires ventilation). The controller detects the drop in voltage 1070 and closes the power relay to allow for Level 2 EV charging (State C) 1080. During charging the controller is running the safety checks 1090 and will terminate charge 1099 if needed due to a failed test (1095 Yes). The controller has an integrated Energy Management circuit to prevent overloading the existing service (combination of our EVSE and the pre-existing load). Our status LED, will emit a different color for each State of charge.

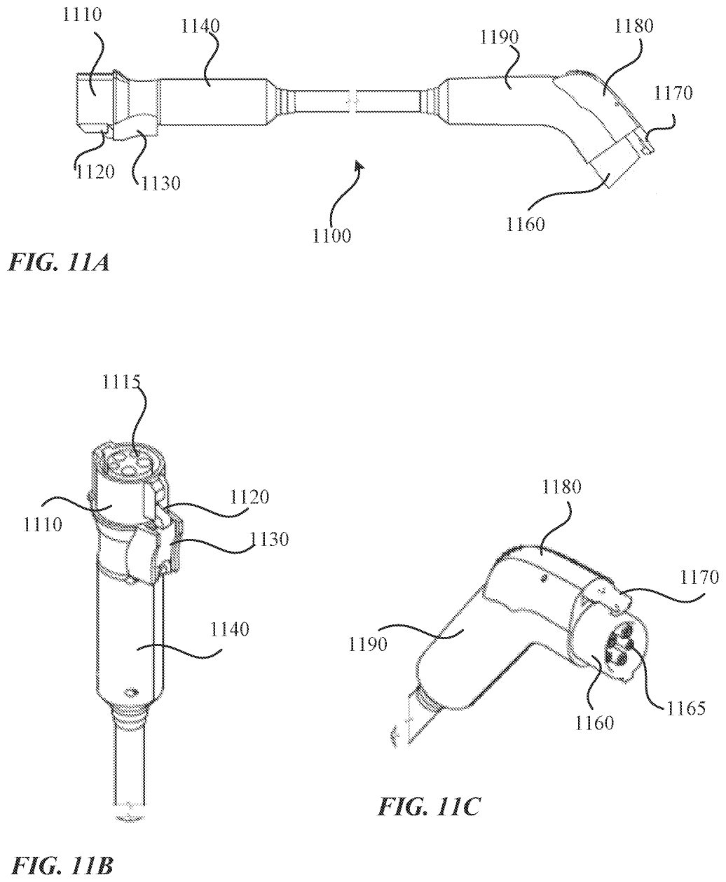

FIGS. 11A-C illustrate an example untethered EV cable 1100 that could be utilized to provide connectivity and charging between EVSEs and EVs. The cable 1100 could be the cable 800 illustrated connecting to the EV inlet connector 470 in FIG. 8. The cable 1100 includes a first end for connecting to an EV power source (e.g., EV inlet port 470) and a second end for connecting to an EV. The first end includes a connector 1110 for connecting to the EV power source, a latch 1120 for securing the connector 1110 in the power source, a button 1130 for disengaging the latch 1120, and a handle 1140 for holding the first end of the cable 800. As illustrated the handle 1140 is configured so that the cable 1100 plugs straight into the power source. The connector 1110 is a male connector that includes a plurality of holes 1115 each housing a pin located therein. Each of the pins is to be received by a corresponding insulated receptacle in a female connector on the power source. The second end includes a connector 1160 for connecting to the EV, a latch 1170 for securing the connector 1160 in the EV, a button 1180 for disengaging the latch 1170, and a handle 1190 for holding the second end of the cable 1100. As illustrated the handle 1190 is configured at an angle so that the cable 1100 extends away from the EV at an angle. The connector 1160 is a female connector that includes a plurality of insulated receptacles 1165 extending therefrom. Each of the insulted receptacles 1165 is to receive a corresponding pin located within an opening in a male connector on the EV.

The untethered cable is not limited to being plugged into a specific EV charging source. As one skilled in the art would recognize, different power sources may have varying current ratings. Accordingly, plugging a lower rated untethered cable into a higher rated power source could be dangerous as it may, for example, overheat and destroy the cable. According to one embodiment, the cable includes a circuit board that is capable of measuring the duty cycle of the power provided to determine the rating of the power source. If the rating is at or below the rating of the cable, no changes are made to the power provided by the power source. However, if it is determined that the rating of the power source is higher than the rating of the cable the circuit board may reduce the rating of the power provided to the maximum rating of the cable.

The fused disconnect 430 has been disclosed with regard to being used in a meter collar providing EV charging. However, the fused disconnect is not limited thereto. Rather, the fused disconnect can be used in other types of EV charging stations. Furthermore, the fused disconnect can be used in other electrical applications where a removable fuse and a manual switch are desired.

Moreover, the fused disconnect provided the externally accessible overcurrent protection device and the manual switch that are required by UL. It should be noted that a breaker could be utilized instead of a fuse without departing from the current scope. Furthermore, a separate manual switch and externally accessible overcurrent protection device (e.g., fuse, breaker) could be utilized without departing from the current scope.

Although the invention has been illustrated by reference to specific embodiments, it will be apparent that the invention is not limited thereto as various changes and modifications may be made thereto without departing from the scope. Reference to “one embodiment” or “an embodiment” means that a particular feature, structure or characteristic described therein is included in at least one embodiment. Thus, the appearances of the phrase “in one embodiment” or “in an embodiment” appearing in various places throughout the specification are not necessarily all referring to the same embodiment.

The various embodiments are intended to be protected broadly within the spirit and scope of the appended claims.

The invention claimed is:

1. An electric meter collar housing an electric vehicle supply equipment (EVSE), the collar comprising:
a housing configured to fit within an electric meter receptacle of an electrical interface and to receive an electric meter;
a first supply side jaw blade configured to plug into a first supply side socket in the electric meter receptacle to receive a first phase of a voltage from a utility company and to receive a first supply side connector of the electric meter to provide the first phase of the voltage to the electric meter;
a second supply side jaw blade configured to plug into a second supply side socket in the electric meter receptacle to receive a second phase of the voltage from the utility company and to receive a second supply side connector of the electric meter to provide the second phase of the voltage to the electric meter;
a first load side jaw blade configured to receive a first load side connector of the electric meter to receive the first phase of the voltage and to plug into a first load side socket in the electric meter receptacle to provide the first phase of the voltage to a consumer;
a second load side jaw blade configured to receive a second load side connector of the electric meter to receive the second phase of the voltage and to plug into a second load side socket in the electric meter receptacle to provide the second phase of the voltage to the consumer;
a first fuse coupled to the first phase of the voltage to determine if current drawn by a load on the first phase of the voltage exceeds a defined current;
a second fuse coupled to the second phase of the voltage to determine if current drawn by the load on the second phase of the voltage exceeds the defined current;
a controller to control operation of the EVSE, wherein controller is coupled to the first fuse and the second fuse to receive the first phase and the second phase of the voltage;
an EV cable connection to utilize the first and the second phase of the voltage to provide charging of an EV via an EV cable;
a relay coupled between the first fuse and the second fuse and the EV cable connection, wherein the relay is controlled by the EV controller; and
a ground fault circuit interrupter (GFCI) current transformer coupled between the relay and the EV cable connection to detect ground faults during EV charging.

2. The collar of claim 1, wherein the first fuse and the second fuse are coupled to the first phase and the second phase of the voltage via the first and the second supply side j aw blades.

3. The collar of claim 1, wherein the first fuse and the second fuse are coupled to the first phase and the second phase of the voltage via the first and the second load side jaw blades.

4. The collar of claim 1, further comprising
a first current transformer coupled to the first phase of the voltage to measure the current utilized thereby for EV charging;
a second current transformer coupled to the second phase of the voltage to measure the current utilized thereby for EV charging, wherein the measured current is provided to the controller to calculate wattage.

5. The collar of claim 4, wherein the controller communicates wattage usage to a service provider.

6. The collar of claim 1, wherein the controller and the EV communicate charging status via a pilot pin.

7. The collar of claim 1, further comprising a ground jaw blade configured to plug into ground socket in the electric meter receptacle, wherein the controller and the EV cable connection are connected to the ground jaw blade to provide grounding.

8. The collar of claim 1, further comprising a ground wire connected to the controller and the EV cable connection and extending from the collar for being secured to a ground terminal in the electric meter receptacle to provide grounding for the controller and the EV cable connection.

9. The collar of claim 1, wherein the first fuse and the second fuse are located external to the housing.

10. The collar of claim 1, further comprising an external switch to control power provided to the EV controller.

11. The collar of claim 10, wherein the first and the second fuse are integrated in the external switch.

12. The collar of claim 1, wherein the EV cable connector is an EV connector inlet having a plurality of insulated receptacles to receive pins of an untethered EV cable.

13. An electrical interface capable of charging electric vehicles (EVs), wherein the interface is to receive a first phase of a voltage and a second phase of the voltage from a utility company and provide the first phase of the voltage and the second phase of the voltage to a customer, the electrical interface comprising:
a meter receptacle that includes:
a first supply side socket to provide the first phase of the voltage;
a second supply side socket to provide the second phase of the voltage;
a first load side socket to receive the first phase of the voltage; and
a second load side socket to receive the second phase of the voltage;
an electric meter collar to be secured into the meter receptacle, wherein the collar is capable of acting as an electric vehicle supply equipment, wherein the collar includes:
a first supply side jaw blade to plug into and receive the first phase of the voltage from the first supply side socket;
a second supply side jaw blade to plug into and receive the second phase of the voltage from the second supply side socket;
a first load side jaw blade to plug into provide the first phase of the voltage to the first load side socket;
a second load side jaw blade to plug into and provide the second phase of the voltage to the second load side socket;
a fused disconnect connectable to the first phase of the voltage and the second phase of the voltage when inserted into a powered receptacle, wherein the fused disconnect includes a first fuse coupled to the first phase of the voltage to determine if current drawn by a load on the first phase of the voltage exceeds a defined current and a second fuse coupled to the second phase of the voltage to determine if current drawn by the load on the second phase of the voltage exceeds the defined current;
a controller to control operation of the EVSE, wherein controller is coupled to the first fuse and the second fuse to receive the first phase and the second phase of the voltage;
an EV connector inlet having a plurality of insulated receptacles to receive pins of an untethered EV cable, wherein the EV connector inlet is to utilize the first and the second phase of the voltage to provide charging of an EV via an EV cable;
a relay coupled between the first fuse and the second fuse and the EV connector inlet, wherein the relay is controlled by the EV controller;
a ground fault circuit interrupter (GFCI) current transformer coupled between the relay and the EV connector inlet to detect ground faults during EV charging;
a first current transformer coupled to the first phase of the voltage to measure the current utilized thereby for EV charging, wherein the measured current of the first phase of the voltage is provided to the controller; and
a second current transformer coupled to the second phase of the voltage to measure the current utilized thereby for EV charging, wherein the measured current of the second phase of the voltage is provided to the controller; and
an electric meter that includes:
a first supply side connector to plug into and receive the first phase of the voltage from the first supply side jaw blade;
a second supply side connector to plug into and receive the second phase of the voltage from the second supply side jaw blade;
a first load side connector to plug into and provide the first phase of the voltage to the first load side jaw blade; and
a second load side connector to receive the second phase of the voltage;
a third current transformer coupled to the first phase of the voltage to measure the current utilized by the customer;
a fourth current transformer coupled to the second phase of the voltage to measure the current utilized by the customer; and
a watt hour meter to monitor the current utilized.

14. The electrical interface of claim 13, wherein the fused disconnect, the first current transformer and the second current transformer are coupled to the first phase and the second phase of the voltage via the first and the second supply side jaw blades.

15. The electrical interface of claim 13, wherein the fused disconnect, the first current transformer and the second current transformer are coupled to the first phase and the second phase of the voltage via the first and the second load side jaw blades.

16. The electrical interface of claim 13, wherein the controller communicates wattage usage to a service provider.

17. The electrical interface of claim 13, wherein the controller and the EV communicate charging status via a pilot pin.

18. The electrical interface of claim 13, wherein the electric meter collar further includes a hinged cover to securely cover the EV connector inlet when an EV cable is not secured therein.

19. The electrical interface of claim 13, wherein the electric meter collar further includes a hinged cover to securely cover the powered receptacle when the fused disconnect is not secured therein.

20. The electrical interface of claim 13, wherein the power receptacle includes a microswitch that is engaged by the fused disconnect when the fused disconnect is rotated to an on position, wherein the microswitch communicates with the controller.
